(19) United States
(12) Patent Application Publication
(10) Pub. No.: US 2025/0220882 A1
(43) Pub. Date: Jul. 3, 2025

(54) SEMICONDUCTOR DEVICE INCLUDING VERTICAL TRANSISTOR AND METHOD OF MANUFACTURING THE SAME

(71) Applicant: NANYA TECHNOLOGY CORPORATION, NEW TAIPEI CITY (TW)

(72) Inventor: JHEN-YU TSAI, KAOHSIUNG CITY (TW)

(21) Appl. No.: 18/399,798

(22) Filed: Dec. 29, 2023

(51) Int. Cl. H10B 12/00

(52) U.S. Cl. CPC H10B 12/33; H10B 12/05

(57) ABSTRACT

A semiconductor device and a method of manufacturing a semiconductor device are provided. The semiconductor device includes a first vertical transistor. The first vertical transistor includes a first channel region. The first vertical transistor further includes a first word line wrapping the first channel region. The first vertical transistor also includes a first word line dielectric layer between the first channel region and the first word line. The first vertical transistor furthermore includes a first conductive liner between the first word line dielectric layer and the first word line.

### TECHNICAL FIELD

The present disclosure relates to a semiconductor device and a method of manufacturing the same, and more particularly, to a semiconductor device including one or more vertical transistors, and a method of manufacturing the same.

### DISCUSSION OF THE BACKGROUND

A Dynamic Random Access Memory (DRAM) device is a type of random access memory that stores each bit of data in a separate capacitor within an integrated circuit. Typically, DRAM is arranged in a square array of one capacitor and transistor per cell. A vertical transistor has been developed for the 4F² DRAM cell, where F stands for the photolithographic minimum feature width or critical dimension (CD). However, recently DRAM manufacturers face a tremendous challenge on shrinking the memory cell area as the word line spacing and the word line size continue to shrink. For example, resistance of the word lines may increase as the word line widths decrease. Accordingly, there is a demand for a novel structure for reducing word line resistance.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a first vertical transistor. The first vertical transistor may include a first channel region. The first vertical transistor may further include a first word line wrapping the first channel region. The first vertical transistor may also include a first word line dielectric layer between the first channel region and the first word line. The first vertical transistor may furthermore include a first conductive liner between the first word line dielectric layer and the first word line.

Another aspect of the present disclosure provides a semiconductor device. The semiconductor device includes a first vertical transistor and a first barrier layer. The first vertical transistor may include a first channel region. The first vertical transistor may further include a first word line surrounding the first channel region. The first vertical transistor may also include a first word line dielectric layer surrounding the first word line. The first vertical transistor may furthermore include a first conductive liner surrounding the first word line. The first barrier layer is on sidewalls of the first word line and directly contacts the first conductive liner.

Another aspect of the present disclosure provides a method of manufacturing a semiconductor device. The method may include providing a capacitor over a substrate. The method may furthermore include forming a vertical transistor over the capacitor, wherein the vertical transistor includes: a channel region; a word line wrapping the channel region; a word line dielectric layer between the channel region and the word line; and a conductive liner between the word line dielectric layer and the word line.

In the semiconductor device, with the design of the conductive liner, the width of the narrow region of the word line is directly connected and electrically connected to the conductive liner. That is, the distance between the barrier layer and the word line dielectric layer (e.g., the narrow region of the word line) is increased. Therefore, the conductive liner and the word line can collectively function as a composite word line with an increased width, and thus the word line resistance is reduced, which is advantageous to the electrical function of the semiconductor device.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

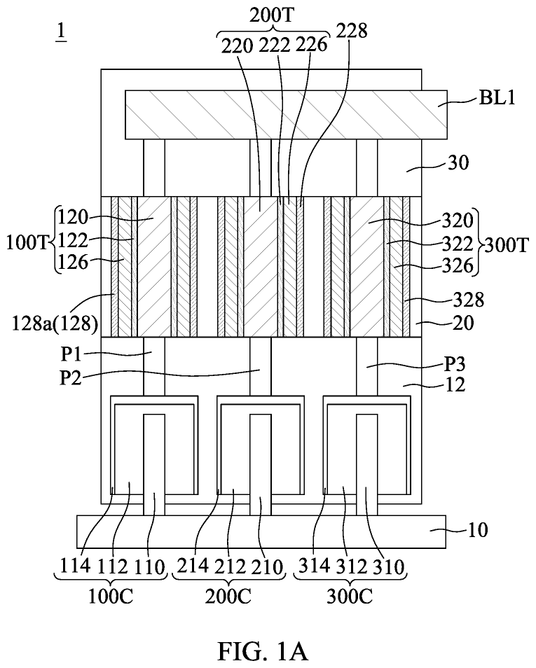

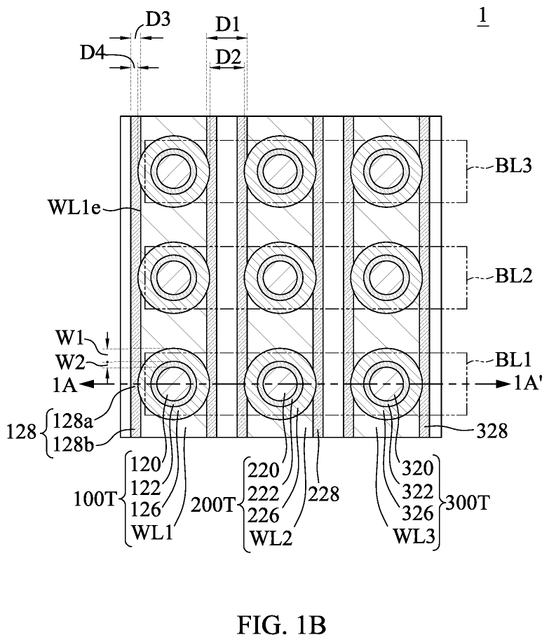

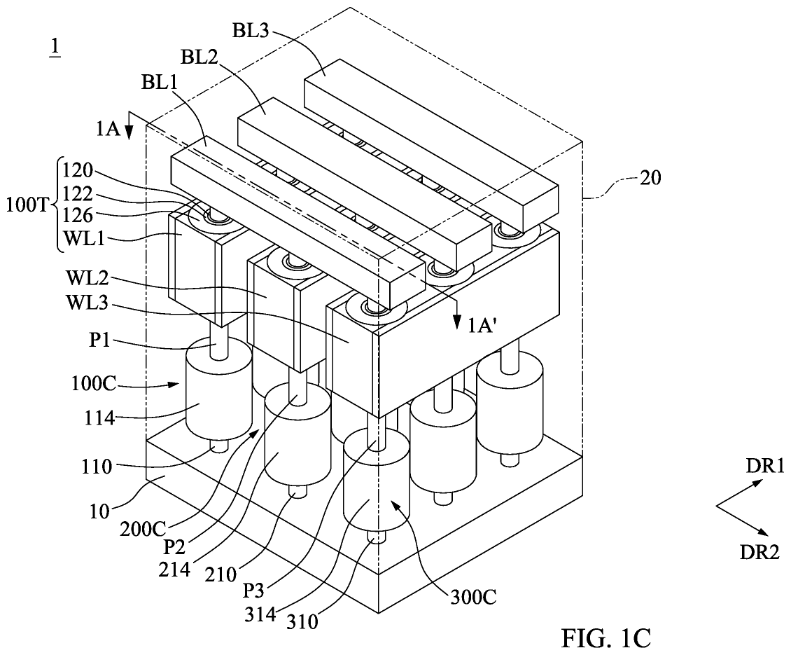

FIG. 1A is a cross-sectional view of a semiconductor device, in accordance with some embodiments of the present disclosure.

FIG. 1B is a top view of a semiconductor device, in accordance with some embodiments of the present disclosure.

FIG. 1C is a perspective view of a semiconductor device, in accordance with some embodiments of the present disclosure.

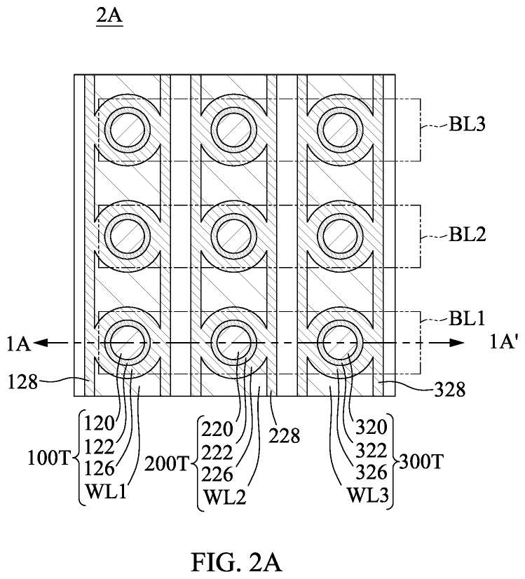

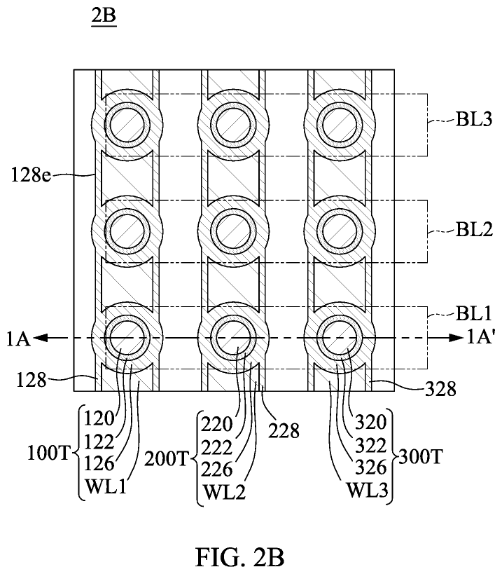

FIG. 2A is a top view of a semiconductor device, in accordance with some embodiments of the present disclosure.

FIG. 2B is a top view of a semiconductor device, in accordance with some embodiments of the present disclosure.

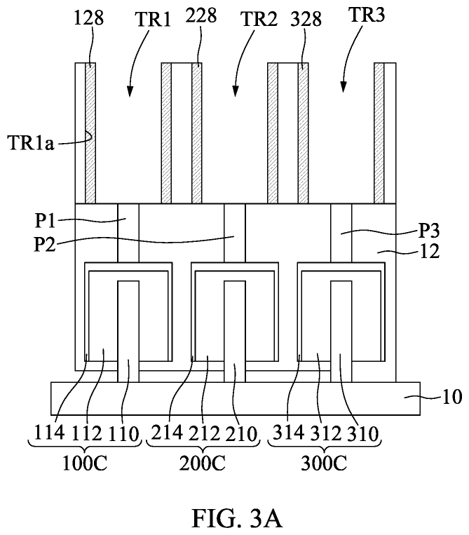

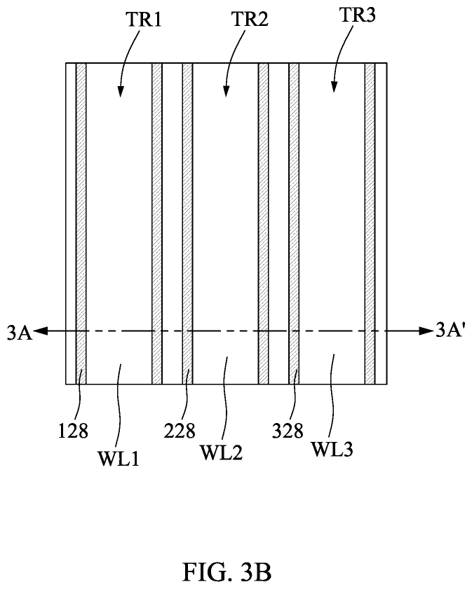

FIG. 3A illustrates one or more stages of a method of manufacturing a semiconductor device, in accordance with some embodiments of the present disclosure.

FIG. 3B illustrates one or more stages of a method of manufacturing a semiconductor device, in accordance with some embodiments of the present disclosure.

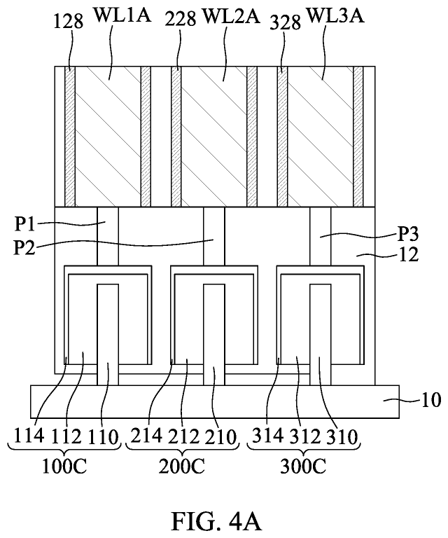

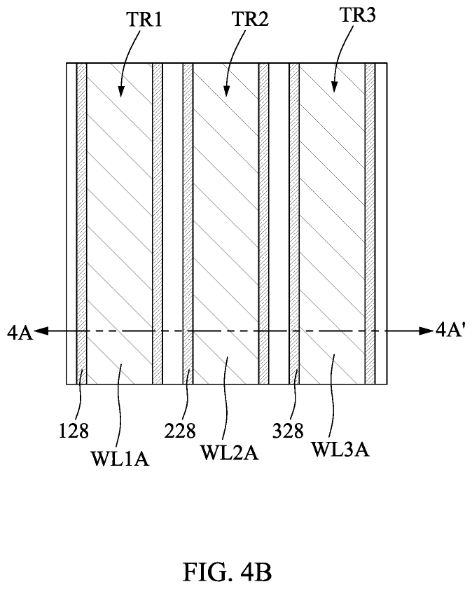

FIG. 4A illustrates one or more stages of a method of manufacturing a semiconductor device, in accordance with some embodiments of the present disclosure.

FIG. 4B illustrates one or more stages of a method of manufacturing a semiconductor device, in accordance with some embodiments of the present disclosure.

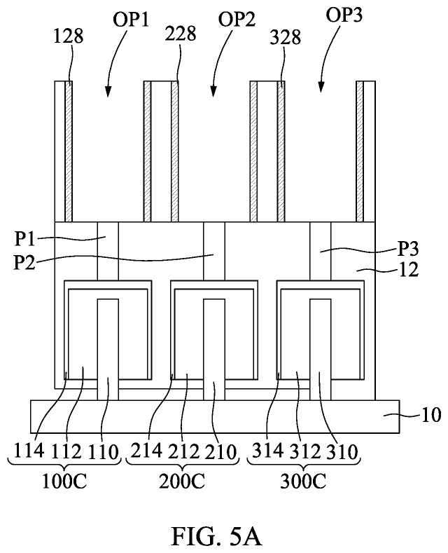

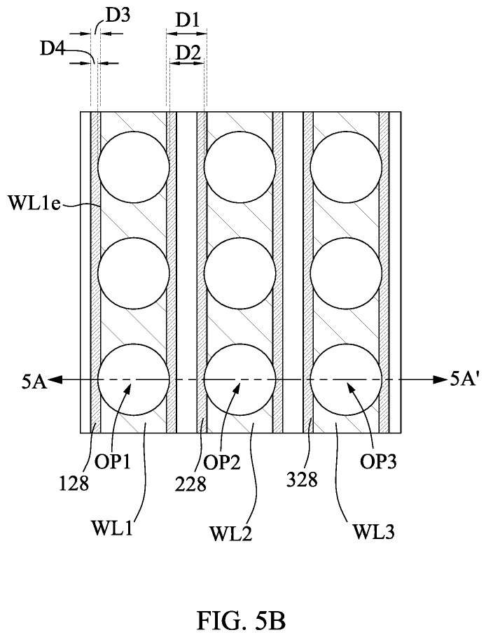

FIG. 5A illustrates one or more stages of a method of manufacturing a semiconductor device, in accordance with some embodiments of the present disclosure.

FIG. 5B illustrates one or more stages of a method of manufacturing a semiconductor device, in accordance with some embodiments of the present disclosure.

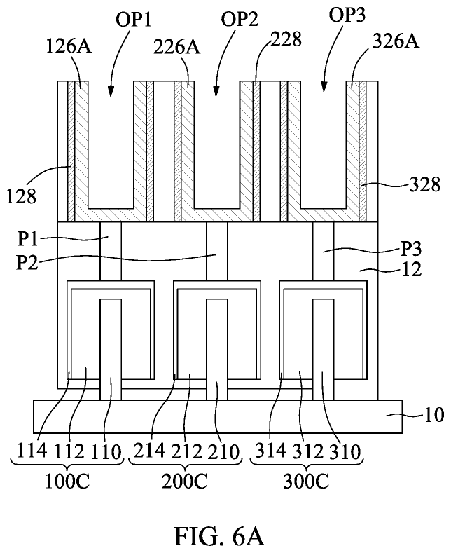

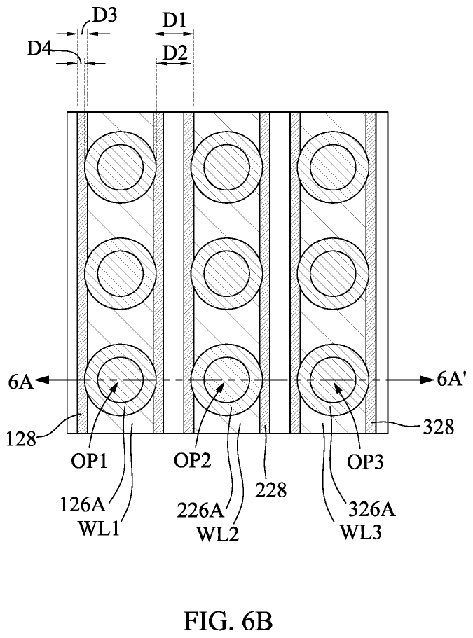

FIG. 6A illustrates one or more stages of a method of manufacturing a semiconductor device, in accordance with some embodiments of the present disclosure.

FIG. 6B illustrates one or more stages of a method of manufacturing a semiconductor device, in accordance with some embodiments of the present disclosure.

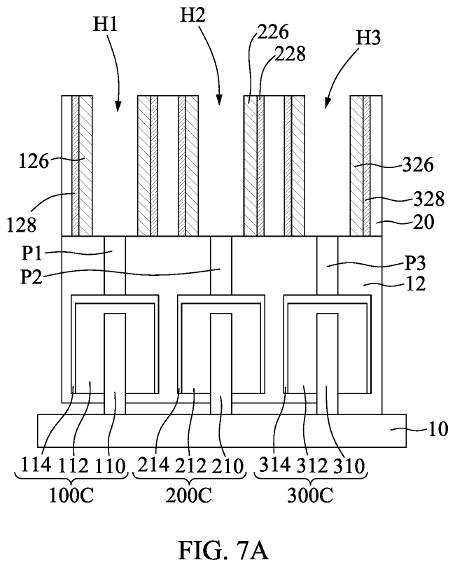

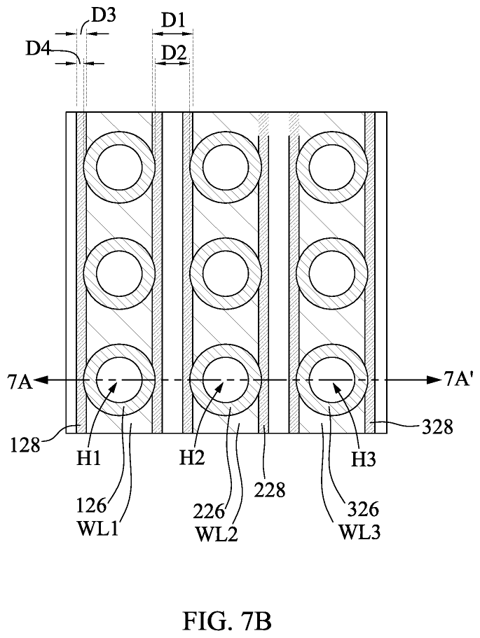

FIG. 7A illustrates one or more stages of a method of manufacturing a semiconductor device, in accordance with some embodiments of the present disclosure.

FIG. 7B illustrates one or more stages of a method of manufacturing a semiconductor device, in accordance with some embodiments of the present disclosure.

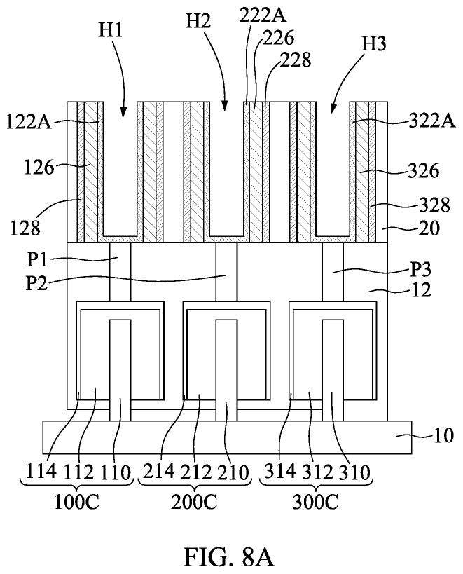

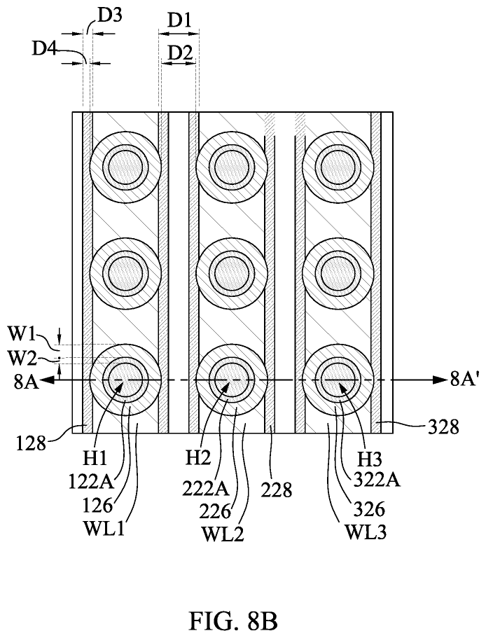

FIG. 8A illustrates one or more stages of a method of manufacturing a semiconductor device, in accordance with some embodiments of the present disclosure.

FIG. 8B illustrates one or more stages of a method of manufacturing a semiconductor device, in accordance with some embodiments of the present disclosure.

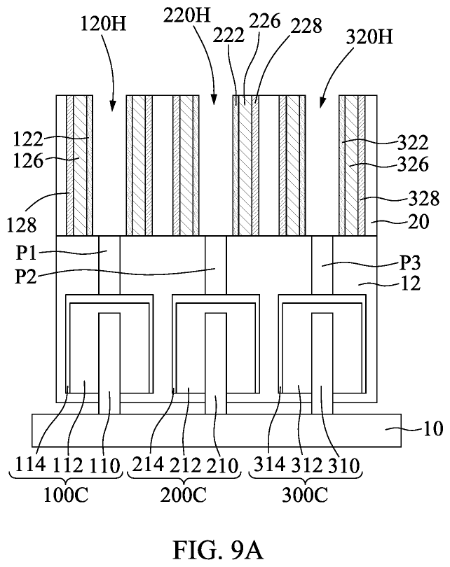

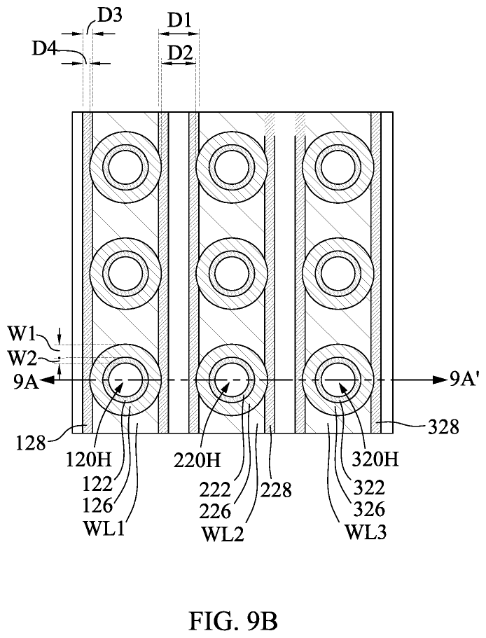

FIG. 9A illustrates one or more stages of a method of manufacturing a semiconductor device, in accordance with some embodiments of the present disclosure.

FIG. 9B illustrates one or more stages of a method of manufacturing a semiconductor device, in accordance with some embodiments of the present disclosure.

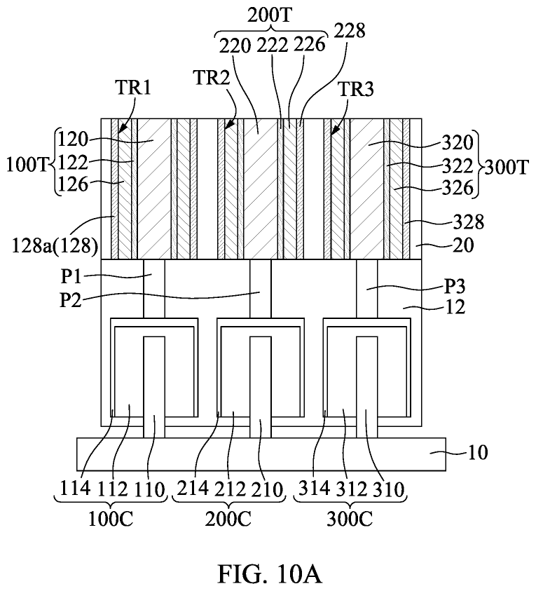

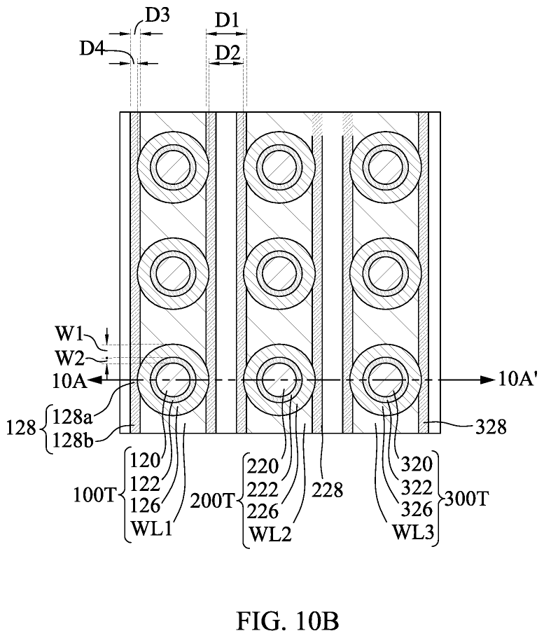

FIG. 10A illustrates one or more stages of a method of manufacturing a semiconductor device, in accordance with some embodiments of the present disclosure.

FIG. 10B illustrates one or more stages of a method of manufacturing a semiconductor device, in accordance with some embodiments of the present disclosure.

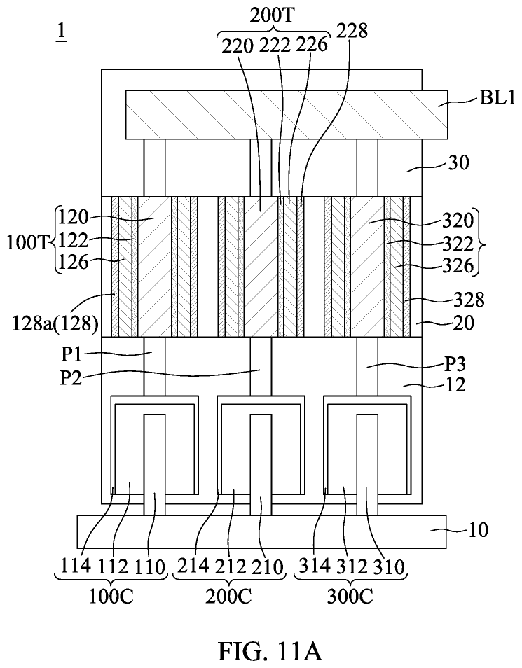

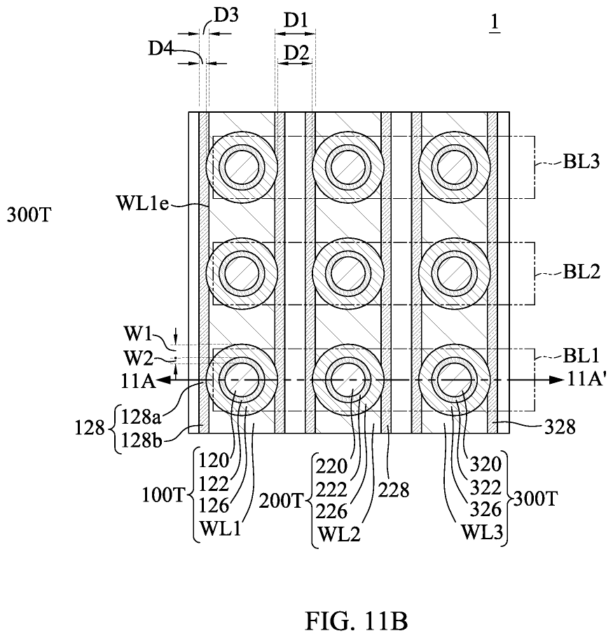

FIG. 11A illustrates one or more stages of a method of manufacturing a semiconductor device, in accordance with some embodiments of the present disclosure.

FIG. 11B illustrates one or more stages of a method of manufacturing a semiconductor device, in accordance with some embodiments of the present disclosure.

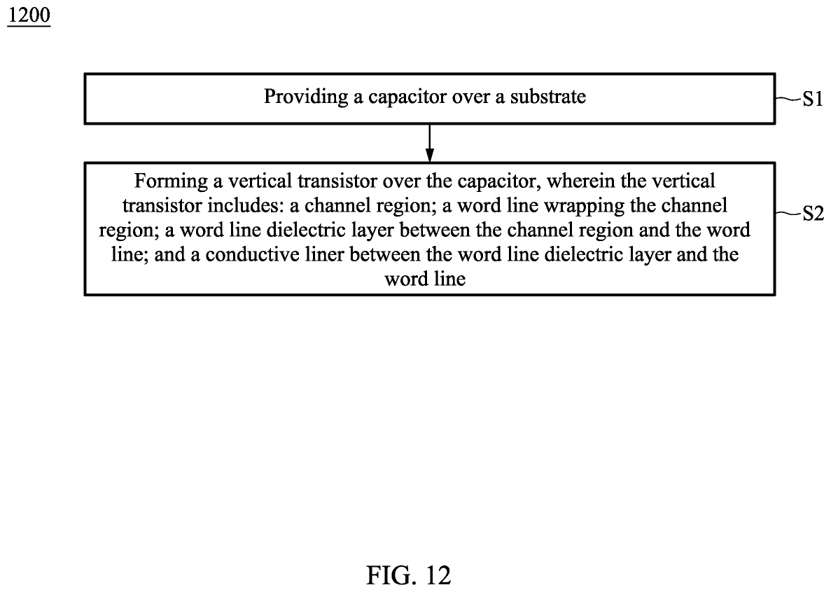

FIG. 12 is a flowchart illustrating a method of manufacturing a semiconductor device, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1A is a cross-sectional view of a semiconductor device 1, in accordance with some embodiments of the present disclosure. FIG. 1B is a top view of a semiconductor device 1, in accordance with some embodiments of the present disclosure. FIG. 1C is a perspective view of a semiconductor device 1, in accordance with some embodiments of the present disclosure. In some embodiments, FIG. 1A is a cross-sectional view along a line 1A-1A′ in FIG. 1B. In some embodiments, FIG. 1A is a cross-sectional view along a line 1A-1A′ in FIG. 1C.

The semiconductor device 1 may include a substrate 10, capacitors 100C, 200C, and 300C, dielectric layers 12, 20, and 30, vertical transistors 100T, 200T, and 300T, barrier layers 128, 228, and 328, pillars P1, P2, and P3, and bit lines BL1, BL2, and BL3.

In some embodiments, the substrate 10 may be a semiconductor substrate. In some embodiments, the substrate 10 may include conductive structures such as contact plugs (not shown) disposed thereon.

In some embodiments, the capacitors 100C, 200C, and 300C are disposed on the substrate 10. In some embodiments, the capacitors 100C, 200C, and 300C are disposed under the vertical transistors 100T, 200T, and 300T, respectively.

In some embodiments, the capacitor 100C includes a pillar as an electrode 110, an insulating layer 112, and an electrode 114. In some embodiments, the electrode 110 includes conductive material such as tungsten, copper, or the like. Although the electrode 110 shown in FIGS. 1A and 1C is columnar, but the shape of the electrode 110 is not limited thereto. In some embodiments, the insulating layer 112 covers and surrounds the electrode 110. In some embodiments, the insulating layer 112 includes silicon oxide, tungsten oxide, copper oxide, aluminum oxide, hafnium oxide, or the like. In some embodiments, the electrode 114 covers and surrounds the insulating layer 112. In some embodiments, the electrode 114 includes conductive material such as tungsten, copper, or the like. In some examples, the material of the electrode 114 may be same as the electrode 110.

In some embodiments, the capacitor 200C includes a pillar as an electrode 210, an insulating layer 212, and an electrode 214. In some embodiments, the electrode 210 includes conductive material such as tungsten, copper, or the like. Although the electrode 210 shown in FIGS. 1A and 1C is columnar, but the shape of the electrode 210 is not limited thereto. In some embodiments, the insulating layer 212 covers and surrounds the electrode 210. In some embodiments, the insulating layer 212 includes silicon oxide, tungsten oxide, copper oxide, aluminum oxide, hafnium oxide, or the like. In some embodiments, the electrode 214 covers and surrounds the insulating layer 212. In some embodiments, the electrode 214 includes conductive material such as tungsten, copper, or the like. In some examples, the material of the electrode 214 may be same as the electrode 210.

In some embodiments, the capacitor 300C includes a pillar as an electrode 310, an insulating layer 312, and an electrode 314. In some embodiments, the electrode 310 includes conductive material such as tungsten, copper, or the like. Although the electrode 310 shown in FIGS. 1A and 1C is columnar, but the shape of the electrode 310 is not limited thereto. In some embodiments, the insulating layer 312 covers and surrounds the electrode 310. In some embodiments, the insulating layer 312 includes silicon oxide, tungsten oxide, copper oxide, aluminum oxide, hafnium oxide, or the like. In some embodiments, the electrode 314 covers and surrounds the insulating layer 312. In some embodiments, the electrode 314 includes conductive material such as tungsten, copper, or the like. In some examples, the material of the electrode 314 may be same as the electrode 310.

In some embodiments, the dielectric layer 12 covers the capacitors 100C, 200C, and 300C. Specifically, the vertical transistors 100T, 200T, and 300T are disposed on the dielectric layer 12 and are respectively aligned with the capacitors 100C, 200C, and 300C.

In some embodiments, the vertical transistor 100T includes a channel region 120, a word line dielectric layer 122, a conductive liner 126, and a word line WL1. In some embodiments, the channel region 120 includes silicon or oxide semiconductor. Specifically, a pillar P1 may be a silicon pillar or an oxide semiconductor pillar, and a portion of the pillar P1 functions as a channel of the vertical transistor 100T (i.e., the channel region 120). In some embodiments, the word line WL1 extends along a direction DR1 and wraps the channel region 120. In some embodiments, the word line WL1 includes tungsten (W), copper (Cu), or molybdenum (Mo), but is not limited thereto. In some embodiments, the word line dielectric layer 122 is disposed between the channel region 120 and the word line WL1. In some embodiments, the channel region 120 is encircled by the word line dielectric layer 122. In some embodiments, the word line dielectric layer 122 may include one or more dielectric materials such as silicon oxide.

In some embodiments, the conductive liner 126 is between the word line dielectric layer 122 and the word line WL1. In some embodiments, the conductive liner 126 surrounds the word line dielectric layer 122. In some embodiments, the conductive liner 126 directly contacts the word line dielectric layer 122 and the word line

WL1. In some embodiments, the word line WL1 surrounds the conductive liner 126. In some embodiments, a resistance of the conductive liner 126 is lower than a resistance of the word line WL1. In some embodiments, a width W1 of the conductive liner 126 is greater than a width W2 of the word line dielectric layer 122. In some embodiments, the conductive liner 126 is partially protruded from an edge WL1e of the word line WL1. In some embodiments, the conductive liner 126 includes titanium (Ti), titanium nitride (TiN), nickel (Ni), or cobalt (Co), but is not limited thereto.

In some embodiments, the vertical transistor 200T is adjacent to the vertical transistor 100T. In some embodiments, the vertical transistor 200T includes a channel region 220, a word line dielectric layer 222, a conductive liner 226, and a word line WL2. In some embodiments, the channel region 220 includes silicon or oxide semiconductor. Specifically, a pillar P2 may be a silicon pillar or an oxide semiconductor pillar, and a portion of the pillar P2 functions as a channel of the vertical transistor 200T (i.e., the channel region 220). In some embodiments, the word line WL2 extends along the direction DR1 and wraps the channel region 220. In some embodiments, the word line WL2 includes tungsten (W), copper (Cu), or molybdenum (Mo), but is not limited thereto. In some embodiments, the word line dielectric layer 222 is disposed between the channel region 220 and the word line WL2. In some embodiments, the channel region 220 is encircled by the word line dielectric layer 222. In some embodiments, the word line dielectric layer 222 may include one or more dielectric materials such as silicon oxide.

In some embodiments, the conductive liner 226 is between the word line dielectric layer 222 and the word line WL2. In some embodiments, the conductive liner 226 surrounds the word line dielectric layer 222. In some embodiments, the conductive liner 226 directly contacts the word line dielectric layer 222 and the word line WL2. In some embodiments, the word line WL2 surrounds the conductive liner 226. In some embodiments, a resistance of the conductive liner 226 is lower than a resistance of the word line WL2. In some embodiments, a width of the conductive liner 226 is greater than a width of the word line dielectric layer 222. In some embodiments, the conductive liner 226 is partially protruded from an edge of the word line WL2. In some embodiments, the conductive liner 226 includes titanium (Ti), titanium nitride (TiN), nickel (Ni), or cobalt (Co), but is not limited thereto. In some embodiments, a distance D2 between the conductive liner 126 and the conductive liner 226 is less than a distance D1 between the word line WL1 and the word line WL2.

In some embodiments, the vertical transistor 300T is adjacent to the vertical transistor 200T. In some embodiments, the vertical transistor 300T includes a channel region 320, a word line dielectric layer 322, a conductive liner 326, and a word line WL3. In some embodiments, the channel region 320 includes silicon or oxide semiconductor. Specifically, a pillar P3 may be a silicon pillar or an oxide semiconductor pillar, and a portion of the pillar P3 functions as a channel of the vertical transistor 300T (i.e., the channel region 320). In some embodiments, the word line WL3 extends along the direction DR1 and wraps the channel region 320. In some embodiments, the word line WL3 includes tungsten (W), copper (Cu), or molybdenum (Mo), but is not limited thereto. In some embodiments, the word line dielectric layer 322 is disposed between the channel region 320 and the word line WL3. In some embodiments, the channel region 320 is encircled by the word line dielectric layer 322. In some embodiments, the word line dielectric layer 322 may include one or more dielectric materials such as silicon oxide.

In some embodiments, the conductive liner 326 is between the word line dielectric layer 322 and the word line WL3. In some embodiments, the conductive liner 326 surrounds the word line dielectric layer 322. In some embodiments, the conductive liner 326 directly contacts the word line dielectric layer 322 and the word line WL3. In some embodiments, the word line WL3 surrounds the conductive liner 326. In some embodiments, a resistance of the conductive liner 326 is lower than a resistance of the word line WL3. In some embodiments, a width of the conductive liner 326 is greater than a width of the word line dielectric layer 322. In some embodiments, the conductive liner 326 is partially protruded from an edge of the word line WL3. In some embodiments, the conductive liner 326 includes titanium (Ti), titanium nitride (TiN), nickel (Ni), or cobalt (Co), but is not limited thereto.

In some embodiments, the dielectric layer 20 is disposed or formed over the dielectric layer 12. In some embodiments, the dielectric layer 20 encapsulates the vertical transistors 100T, 200T, and 300T. In some embodiments, the dielectric layer 20 directly contacts the conductive liner 126. In some embodiments, the dielectric layer 20 directly contacts the conductive liner 226. In some embodiments, the dielectric layer 20 directly contacts the conductive liner 326. In some embodiments, a distance D4 between the dielectric layer 20 and the conductive liner 126 is less than a distance D3 between the dielectric layer 20 and the word line WL1.

In some embodiments, the barrier layer 128 is on sidewalls of the word line WL1. In some embodiments, the barrier layer 128 directly contacts the conductive liner 126. In some embodiments, the barrier layer 128 has a non-uniform width. In some embodiments, the barrier layer 128 includes a portion 128a contacting the conductive liner 126 and a portion 128b contacting the word line WL1. In some embodiments, a width D3 of the portion 128a of the barrier layer 128 is less than a width D4 of the portion 128b of the first barrier layer 128. In some embodiments, the conductive liner 126 is partially protruded into the barrier layer 128. In some embodiments, the barrier layer 128 directly contacts the dielectric layer 20. In some embodiments, the barrier layer 128 includes titanium (Ti), titanium nitride (TiN), nickel (Ni), or cobalt (Co), but is not limited thereto.

In some embodiments, the barrier layer 228 is on sidewalls of the word line WL2. In some embodiments, the barrier layer 228 directly contacts the conductive liner 226. In some embodiments, the barrier layer 228 has a non-uniform width. In some embodiments, the barrier layer 228 includes a portion contacting the conductive liner 226 and a portion contacting the word line WL2. In some embodiments, the two portions of the barrier layer 228 have different widths. In some embodiments, the conductive liner 226 is partially protruded into the barrier layer 228. In some embodiments, the barrier layer 228 directly contacts the dielectric layer 20. In some embodiments, the barrier layer 228 includes titanium (Ti), titanium nitride (TiN), nickel (Ni), or cobalt (Co), but is not limited thereto.

In some embodiments, the barrier layer 328 is on sidewalls of the word line WL3. In some embodiments, the barrier layer 328 directly contacts the conductive liner 326. In some embodiments, the barrier layer 328 has a non-uniform width. In some embodiments, the barrier layer 328 includes a portion contacting the conductive liner 326 and a portion contacting the word line WL3. In some embodiments, the two portions of the barrier layer 328 have different widths. In some embodiments, the conductive liner 326 is partially protruded into the barrier layer 328. In some embodiments, the barrier layer 328 directly contacts the dielectric layer 20. In some embodiments, the barrier layer 328 includes titanium (Ti), titanium nitride (TiN), nickel (Ni), or cobalt (Co), but is not limited thereto.

In some embodiments, the dielectric layer 30 is disposed or formed over the dielectric layer 20. In some embodiments, the dielectric layer 30 includes a material same as the dielectric layers 12 and 20. In some examples, the dielectric layer 30 includes oxide, nitride, or a low k material.

In some embodiments, the bit lines BL1, BL2, and BL3 are over the vertical transistors 100T, 200T, and 300T. In some embodiments, the bit lines BL1, BL2, and BL3 cross over the word lines WL1, WL2, and WL3. In some embodiments, the bit lines BL1, BL2, and BL3 extend along a direction DR2 perpendicular to the direction DR1. In some embodiments, the bit lines BL1, BL2, and BL3 include includes tungsten (W), copper (Cu), or molybdenum (Mo), but is not limited thereto.

The semiconductor device 1 may be a Dynamic Random Access Memory (DRAM) arranged in an array of one capacitor and transistor per cell. On the assumption that a pitch of each of word line and bit line is 2F, a horizontal size of memory cell can be 4F². The semiconductor device 1 can have an area of approximately 4F² or less, where F is the minimum lithographic feature size.

FIG. 2A is a top view of a semiconductor device 2A, in accordance with some embodiments of the present disclosure. In some embodiments, FIG. 1A may show a cross-sectional view along a line 1A-1A′ in FIG. 2A.

In some embodiments, the conductive liner 126 is partially integrally formed with the barrier layer 128. In some embodiments, the conductive liner 126 and the barrier layer 128 may be formed of or include the same material, e.g., Ti or TiN.

In some embodiments, the conductive liner 226 is partially integrally formed with the barrier layer 228. In some embodiments, the conductive liner 226 and the barrier layer 228 may be formed of or include the same material, e.g., Ti or TiN.

In some embodiments, the conductive liner 326 is partially integrally formed with the barrier layer 328. In some embodiments, the conductive liner 326 and the barrier layer 328 may be formed of or include the same material, e.g., Ti or TiN.

FIG. 2B is a top view of a semiconductor device 2B, in accordance with some embodiments of the present disclosure. In some embodiments, FIG. 1A may show a cross-sectional view along a line 1A-1A′ in FIG. 2B.

In some embodiments, the conductive liner 126 is partially protruded from an edge 128e of the barrier layer 128. In some embodiments, the conductive liner 126 directly contacts the dielectric layer 20. In some embodiments, the conductive liner 126 is partially integrally formed with the barrier layer 128. In some embodiments, the conductive liner 126 and the barrier layer 128 may be formed of or include the same material, e.g., Ti or TiN.

In some embodiments, the conductive liner 226 is partially protruded from an edge of the barrier layer 228. In some embodiments, the conductive liner 226 directly contacts the dielectric layer 20. In some embodiments, the conductive liner 226 is partially integrally formed with the barrier layer 228. In some embodiments, the conductive liner 226 and the barrier layer 228 may be formed of or include the same material, e.g., Ti or TiN.

In some embodiments, the conductive liner 326 is partially protruded from an edge of the barrier layer 328. In some embodiments, the conductive liner 326 directly contacts the dielectric layer 20. In some embodiments, the conductive liner 326 is partially integrally formed with the barrier layer 328. In some embodiments, the conductive liner 326 and the barrier layer 328 may be formed of or include the same material, e.g., Ti or TiN.

According to some embodiments of the present disclosure, with the design of the conductive liner, the width of the narrow region of the word line is directly connected and electrically connected to the conductive liner. That is, the distance between the barrier layer and the word line dielectric layer (e.g., the narrow region of the word line) is increased. Therefore, the conductive liner and the word line can collectively function as a composite word line with an increased width, and thus the word line resistance is reduced, which is advantageous to the electrical function of the semiconductor device.

FIG. 3A to FIG. 11B illustrate various stages of a method of manufacturing a semiconductor device 1, in accordance with some embodiments of the present disclosure.

FIG. 3A illustrates one or more stages of a method of manufacturing a semiconductor device, in accordance with some embodiments of the present disclosure. FIG. 3B illustrates one or more stages of a method of manufacturing a semiconductor device, in accordance with some embodiments of the present disclosure. In some embodiments, FIG. 3A is a cross-sectional view of the structure illustrated in FIG. 3B. In some embodiments, FIG. 3A is a cross-sectional view along a line 3A-3A′ in FIG. 3B.

Referring to FIG. 3A and FIG. 3B, a substrate 10 may be provided, and capacitors 100C, 200C, and 300C may be provided over the substrate 10. In some arrangements, a dielectric layer 12 may be formed to cover or encapsulate the capacitors 100C, 200C, and 300C.

In some embodiments, as illustrated in FIG. 3A and FIG. 3B, trenches TR1, TR2, and TR3 may be formed over the capacitors 100C, 200C, and 300C, respectively. In some embodiments, barrier layers 128, 228, and 328 are formed on sidewalls of the trenches TR1, TR2, and TR3, respectively. In some embodiments, a dielectric layer 20 may be formed over the capacitors 100C, 200C, and 300C, and the trenches TR1, TR2, and TR3 may be formed in the dielectric layer 20. In some embodiments, the dielectric layer 20 defines the trenches TR1, TR2, and TR3.

FIG. 4A illustrates one or more stages of a method of manufacturing a semiconductor device, in accordance with some embodiments of the present disclosure. FIG. 4B illustrates one or more stages of a method of manufacturing a semiconductor device, in accordance with some embodiments of the present disclosure. In some embodiments, FIG. 4A is a cross-sectional view of the structure illustrated in FIG. 4B. In some embodiments, FIG. 4A is a cross-sectional view along a line 4A-4A′ in FIG. 4B.

Referring to FIG. 4A and FIG. 4B, word line materials WL1A, WL2A, and WL3A may be formed in the trenches TR1, TR2, and TR3, respectively.

FIG. 5A illustrates one or more stages of a method of manufacturing a semiconductor device, in accordance with some embodiments of the present disclosure. FIG. 5B illustrates one or more stages of a method of manufacturing a semiconductor device, in accordance with some embodiments of the present disclosure. In some embodiments, FIG. 5A is a cross-sectional view of the structure illustrated in FIG. 5B. In some embodiments, FIG. 5A is a cross-sectional view along a line 5A-5A′ in FIG. 5B.

Referring to FIG. 5A and FIG. 5B, the word line materials WL1A, WL2A, and WL3A may be etched to form word lines WL1, WL2, and WL3 and openings OP1, OP2, and OP3 encircled by the word lines WL1, WL2, and WL3, respectively. In some embodiments, the barrier layers 128, 228, and 328 are etched to form the openings OP1, OP2, and OP3 encircled by the word lines WL1, WL2, and WL3, respectively. In some embodiments, etching the barrier layers 128, 228, and 328 and etching the word line materials WL1A, WL2A, and WL3A are performed in the same operation.

FIG. 6A illustrates one or more stages of a method of manufacturing a semiconductor device, in accordance with some embodiments of the present disclosure. FIG. 6B illustrates one or more stages of a method of manufacturing a semiconductor device, in accordance with some embodiments of the present disclosure. In some embodiments, FIG. 6A is a cross-sectional view of the structure illustrated in FIG. 6B. In some embodiments, FIG. 6A is a cross-sectional view along a line 6A-6A′ in FIG. 6B.

Referring to FIG. 6A and FIG. 6B, conductive liner materials 126A, 226A, and 326A may be formed in the openings OP1, OP2, and OP3, respectively.

FIG. 7A illustrates one or more stages of a method of manufacturing a semiconductor device, in accordance with some embodiments of the present disclosure. FIG. 7B illustrates one or more stages of a method of manufacturing a semiconductor device, in accordance with some embodiments of the present disclosure. In some embodiments, FIG. 7A is a cross-sectional view of the structure illustrated in FIG. 7B. In some embodiments, FIG. 7A is a cross-sectional view along a line 7A-7A′ in FIG. 7B.

Referring to FIG. 7A and FIG. 7B, the conductive liner materials 126A, 226A, and 326A may be etched to form conductive liners 126, 226, and 326 and through holes H1, H2, and H3 encircled by the conductive liners 126, 226, and 326, respectively.

FIG. 8A illustrates one or more stages of a method of manufacturing a semiconductor device, in accordance with some embodiments of the present disclosure. FIG. 8B illustrates one or more stages of a method of manufacturing a semiconductor device, in accordance with some embodiments of the present disclosure. In some embodiments, FIG. 8A is a cross-sectional view of the structure illustrated in FIG. 8B. In some embodiments, FIG. 8A is a cross-sectional view along a line 8A-8A′ in FIG. 8B.

Referring to FIG. 8A and FIG. 8B, word line dielectric materials 122A, 222A, and 322A may be formed in the through hole through holes H1, H2, and H3 encircled by the conductive liners 126, 226, and 326, respectively. In some embodiments, the word line dielectric materials 122A, 222A, and 322A may be deposited in the through holes H1, H2, and H3.

FIG. 9A illustrates one or more stages of a method of manufacturing a semiconductor device, in accordance with some embodiments of the present disclosure. FIG. 9B illustrates one or more stages of a method of manufacturing a semiconductor device, in accordance with some embodiments of the present disclosure. In some embodiments, FIG. 9A is a cross-sectional view of the structure illustrated in FIG. 9B. In some embodiments, FIG. 9A is a cross-sectional view along a line 9A-9A′ in FIG. 9B.

Referring to FIG. 9A and FIG. 9B, the word line dielectric materials 122A, 222A, and 322A may be etched to form word line dielectric layers 122, 222, and 322 and through holes 120H, 220H, and 320H encircled by the word line dielectric layers 122, 222, and 322, respectively. In some embodiments, the word line dielectric layers 122, 222, and 322 are formed on the conductive liners 126, 226, and 326, respectively. The word line dielectric layers 122, 222, and 322 may be formed by a combination of a deposition method such as chemical vapor deposition (CVD), and an etching method such as reactive ion etching (RIE).

FIG. 10A illustrates one or more stages of a method of manufacturing a semiconductor device, in accordance with some embodiments of the present disclosure. FIG. 10B illustrates one or more stages of a method of manufacturing a semiconductor device, in accordance with some embodiments of the present disclosure. In some embodiments, FIG. 10A is a cross-sectional view of the structure illustrated in FIG. 10B. In some embodiments, FIG. 10A is a cross-sectional view along a line 10A-10A′ in FIG. 10B.

Referring to FIG. 10A and FIG. 10B, channel regions 120, 220, and 320 may be formed in the through holes 120H, 220H, and 320H, respectively. As such, vertical transistors 100T, 200T, and 300T are formed in the trenches TR1, TR2, and TR3, respectively. In some embodiments, the through holes 120H, 220H, and 320H are completely filled with one or more semiconductor materials to form the channel regions 120, 220, and 320. A planarization process such as chemical mechanical polishing (CMP) may further be performed, such that top surfaces of the channel regions 120, 220, and 320 may be substantially level with a top surface of the dielectric layer 20, top surfaces of the word lines WL1, WL2, and WL3, and top surfaces of the word line dielectric layers 122, 222, and 322.

FIG. 11A illustrates one or more stages of a method of manufacturing a semiconductor device, in accordance with some embodiments of the present disclosure. FIG. 11B illustrates one or more stages of a method of manufacturing a semiconductor device, in accordance with some embodiments of the present disclosure. In some embodiments, FIG. 11A is a cross-sectional view of the structure illustrated in FIG. 11B. In some embodiments, FIG. 11A is a cross-sectional view along a line 11A-11A′ in FIG. 11B.

Referring to FIG. 11A and FIG. 11B, bit lines BL1, BL2, and BL3 may be formed over the vertical transistors 100T, 200T, and 300T. In some embodiments, a dielectric layer 30 is formed over the dielectric layer 20 and the vertical transistors 100T, 200T, and 300T. In some embodiments, the bit lines BL1, BL2, and BL3 are further formed on the dielectric layer 30 to be positioned over the vertical transistors 100T, 200T, and 300T.

FIG. 12 is a flowchart illustrating a method 1200 of manufacturing a semiconductor device, in accordance with some embodiments of the present disclosure.

The method 1200 begins with operation S1 in which a capacitor is provided over a substrate.

The method 1200 continues with operation S2 in which a vertical transistor is formed over the capacitor. In some embodiments, the vertical transistor includes a channel region, a word line, a word line dielectric layer, and a conductive liner. In some embodiments, the word line wraps the channel region, the word line dielectric layer is between the channel region and the word line, and the conductive liner is between the word line dielectric layer and the word line.

The method 1200 is merely an example, and is not intended to limit the present disclosure beyond what is explicitly recited in the claims. Additional operations can be provided before, during, or after each operations of the method 1200, and some operations described can be replaced, eliminated, or moved around for additional embodiments of the method. In some embodiments, the method 1200 can include further operations not depicted in FIG. 12. In some embodiments, the method 1200 can include one or more operations depicted in FIG. 12.

One aspect of the present disclosure provides a semiconductor device. The semiconductor device includes a first vertical transistor.

The first vertical transistor may include a first channel region. The first vertical transistor may further include a first word line wrapping the first channel region. The first vertical transistor may also include a first word line dielectric layer between the first channel region and the first word line. The first vertical transistor may furthermore include a first conductive liner between the first word line dielectric layer and the first word line.

Another aspect of the present disclosure provides a semiconductor device. The semiconductor device includes a first vertical transistor and a first barrier layer. The first vertical transistor may include a first channel region. The first vertical transistor may further include a first word line surrounding the first channel region. The first vertical transistor may also include a first word line dielectric layer surrounding the first word line. The first vertical transistor may furthermore include a first conductive liner surrounding the first word line. The first barrier layer is on sidewalls of the first word line and directly contacts the first conductive liner.

Another aspect of the present disclosure provides a method of manufacturing a semiconductor device. The method may include providing a capacitor over a substrate. The method may furthermore include forming a vertical transistor over the capacitor, wherein the vertical transistor includes: a channel region; a word line wrapping the channel region; a word line dielectric layer between the channel region and the word line; and a conductive liner between the word line dielectric layer and the word line.

In the semiconductor device, with the design of the conductive liner, the width of the narrow region of the word line is directly connected and electrically connected to the conductive liner. That is, the distance between the barrier layer and the word line dielectric layer (e.g., the narrow region of the word line) is increased. Therefore, the conductive liner and the word line can collectively function as a composite word line with an increased width, and thus the word line resistance is reduced, which is advantageous to the electrical function of the semiconductor device.

Although the present disclosure and its advantages have been described in detail, it should be understood that various changes, substitutions and alterations can be made herein without departing from the spirit and scope of the disclosure as defined by the appended claims. For example, many of the processes discussed can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a first vertical transistor, comprising:
a first channel region;
a first word line wrapping the first channel region;
a first word line dielectric layer between the first channel region and the first word line; and
a first conductive liner between the first word line dielectric layer and the first word line.

2. The semiconductor device of claim 1, wherein the first conductive liner surrounds the first word line dielectric layer.

3. The semiconductor device of claim 2, wherein the first conductive liner directly contacts the first word line dielectric layer and the first word line.

4. The semiconductor device of claim 1, wherein the first word line surrounds the first conductive liner.

5. The semiconductor device of claim 1, wherein a resistance of the first conductive liner is lower than a resistance of the first word line.

6. The semiconductor device of claim 1, wherein a width of the first conductive liner is greater than a width of the first word line dielectric layer.

7. The semiconductor device of claim 1, wherein the first conductive liner is partially protruded from an edge of the first word line.

8. The semiconductor device of claim 1, further comprising a dielectric layer encapsulating the first vertical transistor, wherein a distance between the dielectric layer and the first conductive liner is less than a distance between the dielectric layer and the first word line.

9. The semiconductor device of claim 1, further comprising a second vertical transistor adjacent to the first vertical transistor, the second vertical transistor comprising:
a second channel region;
a second word line wrapping the second channel region;
a second word line dielectric layer between the second channel region and the second word line; and
a second conductive liner between the second word line dielectric layer and the second word line.

10. The semiconductor device of claim 9, wherein a distance between the first conductive liner and the second conductive liner is less than a distance between the first word line and the second word line.

11. A semiconductor device, comprising:
a first vertical transistor, comprising:
a first channel region;
a first word line surrounding the first channel region;
a first word line dielectric layer surrounding the first word line; and
a first conductive liner surrounding the first word line; and
a first barrier layer on sidewalls of the first word line and directly contacting the first conductive liner.

12. The semiconductor device of claim 11, wherein the first barrier layer has a non-uniform width.

13. The semiconductor device of claim 12, wherein the first barrier layer comprises a first portion contacting the first conductive liner and a second portion contacting the first word line.

14. The semiconductor device of claim 13, wherein a width of the first portion of the first barrier layer is less than a width of the second portion of the first barrier layer.

15. The semiconductor device of claim 11, wherein the first conductive liner is partially protruded into the first barrier layer.

16. The semiconductor device of claim 15, wherein the first conductive liner is partially integrally formed with the first barrier layer.

17. The semiconductor device of claim 15, wherein the first conductive liner is partially protruded from an edge of the first barrier layer.

18. The semiconductor device of claim 17, wherein the first conductive liner is partially integrally formed with the first barrier layer.

19. The semiconductor device of claim 17, further comprising a dielectric layer encapsulating the first vertical transistor, wherein the dielectric layer directly contacts the first conductive liner and the first barrier layer.

20. The semiconductor device of claim 11, further comprising a second vertical transistor adjacent to the first vertical transistor, the second vertical transistor comprising:
a second channel region;
a second word line surrounding the first channel region;
a second word line dielectric layer surrounding the first word line; and
a second conductive liner surrounding the first word line; and
a second barrier layer on sidewalls of the second word line and directly contacting the second conductive liner.
